(19) United States
(12) Patent Application Publication
(10) Pub. No.: US 2021/0241067 A1
(43) Pub. Date: Aug. 5, 2021

(54) Hyper-Graph Network Decoders for Algebraic Block Codes

(71) Applicant: Facebook, Inc., Menlo Park, CA (US)

(72) Inventors: Eliya Nachmani, Jerusalem (IL); Lior Wolf, Herzliya (IL)

(21) Appl. No.: 16/782,919

(22) Filed: Feb. 5, 2020

(51) Int. Cl. G06N 3/04; G06N 3/08; G06F 17/17

(52) U.S. Cl. CPC G06N 3/04; G06F 17/17; G06N 3/08

(57) ABSTRACT

In one embodiment, a method includes inputting an encoded message with noise to a neural-networks model comprising a variable and a check layers of nodes, each node being associated with at least one weight and a hyper-network node, updating the weights associated with the variable layer of nodes by processing the encoded message using the hyper-network nodes associated with the variable layer of nodes, generating a first set of outputs by processing the encoded message using the variable layer of nodes and their respective updated weights, updating the weights associated with the check layer of nodes by processing the first set of outputs using the hyper-network nodes associated with the check layer of nodes, and generating a decoded message without noise using the neural-networks model by using at least the first set of outputs and the check layer of nodes and their respective updated weights.

### TECHNICAL FIELD

This disclosure generally relates to data decoding and denoising, and in particular relates to machine learning for such data processing.

### BACKGROUND

Machine learning (ML) is the study of algorithms and mathematical models that computer systems use to progressively improve their performance on a specific task. Machine learning algorithms build a mathematical model of sample data, known as “training data”, in order to make predictions or decisions without being explicitly programmed to perform the task. Machine learning algorithms may be used in applications such as email filtering, detection of network intruders, and computer vision, where it is difficult to develop an algorithm of specific instructions for performing the task. Machine learning is closely related to computational statistics, which focuses on making predictions using computers. The study of mathematical optimization delivers methods, theory, and application domains to the field of machine learning. Data mining is a field of study within machine learning and focuses on exploratory data analysis through unsupervised learning. In its application across business problems, machine learning is also referred to as predictive analytics.

In deep learning, a convolutional neural network (CNN, or ConvNet) is a class of deep neural networks, most commonly applied to analyzing visual imagery. They have applications in image and video recognition, recommender systems, image classification, medical image analysis, and natural language processing. CNNs are regularized versions of multilayer perceptrons. Multilayer perceptrons usually mean fully connected networks, that is, each neuron in one layer is connected to all neurons in the next layer. The “fully-connectedness” of these networks makes them prone to overfitting data. Typical ways of regularization include adding some form of magnitude measurement of weights to the loss function. CNNs take a different approach towards regularization: they take advantage of the hierarchical pattern in data and assemble more complex patterns using smaller and simpler patterns. Therefore, on the scale of connectedness and complexity, CNNs are on the lower extreme.

### SUMMARY OF PARTICULAR EMBODIMENTS

Neural decoders were shown to improve the performance of message passing algorithms for decoding error correcting codes and outperform classical message passing techniques for short BCH codes. The embodiments disclosed herein extend these results to much larger families of algebraic block codes, by performing message passing with graph neural networks and hypernetworks. The parameters of the sub-network at each variable-node in the Tanner graph are obtained from a hypernetwork that receives the absolute values of the current message as input. To add stability, the embodiments disclosed herein employ a simplified version of the arctanh activation that is based on a high order Taylor approximation of this activation function. The embodiments disclosed herein further demonstrate how hypernetworks can be applied to decode polar codes by employing a new formalization of the polar belief propagation decoding scheme. The experimental results show that for a large number of algebraic block codes, from diverse families of codes (BCH, LDPC, Polar), the decoding obtained with the embodiments disclosed herein outperforms the vanilla belief propagation method as well as other learning techniques from the literature. The embodiments disclosed herein demonstrate that the proposed method improves the previous results of neural polar decoders and achieves, for large SNRs, the same bit-error-rate performances as the successive list cancellation method, which is known to be better than any belief propagation decoders and very close to the maximum likelihood decoder.

In particular embodiments, a computing system may input an encoded message with noise to a neural-networks model. In particular embodiments, the neural-networks model may comprise a first layer of nodes and a second layer of nodes. Each node may be associated with at least one weight and a hyper-network node. In particular embodiments, the computing system may update the weights associated with the first layer of nodes by processing the encoded message with noise using the hyper-network nodes associated with the first layer of nodes. The computing system may then generate a first set of outputs by processing the encoded message with noise using the variable first layer of nodes and their respective updated weights. In particular embodiments, the computing system may then update the weights associated with the second layer of nodes by processing the first set of outputs using the hyper-network nodes associated with the second layer of nodes. The computing system may further generate a decoded message without noise using the neural-networks model. In particular embodiments, the generation may comprise using at least the first set of outputs and the second layer of nodes and their respective updated weights.

In particular embodiments, a computing system may input an encoded message with noise to a neural-networks model. In particular embodiments, the neural-networks model may comprise a variable layer of nodes and a check layer of nodes. Each node may be associated with at least one weight and a hyper-network node. In particular embodiments, the computing system may update the weights associated with the variable layer of nodes by processing the encoded message using the hyper-network nodes associated with the variable layer of nodes. The computing system may then generate a first set of outputs by processing the encoded message using the variable layer of nodes and their respective updated weights. In particular embodiments, the computing system may then update the weights associated with the check layer of nodes by processing the first set of outputs using the hyper-network nodes associated with the check layer of nodes. The computing system may further generate a decoded message without noise using the neural-networks model. In particular embodiments, the generation may comprise using at least the first set of outputs and the check layer of nodes and their respective updated weights.

The embodiments disclosed herein are only examples, and the scope of this disclosure is not limited to them. Particular embodiments may include all, some, or none of the components, elements, features, functions, operations, or steps of the embodiments disclosed herein. Embodiments according to the invention are in particular disclosed in the attached claims directed to a method, a storage medium, a system and a computer program product, wherein any feature mentioned in one claim category, e.g. method, may be claimed in another claim category, e.g. system, as well. The dependencies or references back in the attached claims are chosen for formal reasons only. However any subject matter resulting from a deliberate reference back to any previous claims (in particular multiple dependencies) may be claimed as well, so that any combination of claims and the features thereof are disclosed and may be claimed regardless of the dependencies chosen in the attached claims. The subject-matter which may be claimed comprises not only the combinations of features as set out in the attached claims but also any other combination of features in the claims, wherein each feature mentioned in the claims may be combined with any other feature or combination of other features in the claims. Furthermore, any of the embodiments and features described or depicted herein may be claimed in a separate claim and/or in any combination with any embodiment or feature described or depicted herein or with any of the features of the attached claims.

### BRIEF DESCRIPTION OF THE DRAWINGS

FIG. 1A illustrates an example Tanner graph for a linear block code.

FIG. 1B illustrates an example Trellis graph corresponding to FIG. 1A.

FIG. 2 illustrates an example Taylor approximation of the arctanh activation function.

FIG. 3 illustrates an example structure-adaptive hypernetwork architecture for decoding polar codes.

FIG. 4A illustrates example bit error rates (BER) for various values of SNR for Polar (128,96) code.

FIG. 4B illustrates example bit error rates (BER) for various values of SNR for LDPC MacKay (96,48) code.

FIG. 4C illustrates example bit error rates (BER) for various values of SNR for BCH (63,51) code.

FIG. 4D illustrates example bit error rates (BER) for various values of SNR for BCH (63,51) with a deeper network!

FIG. 4E illustrates example bit error rates (BER) for various values of SNR for large and non-regular LDPC including WRAN (384,256) and TU-KL (96,48).

FIG. 5 illustrates example BER for Polar code (128,64).

FIG. 6 illustrates example BER for Polar code (32,16).

FIG. 7 illustrates an example method for decoding messages using a hyper-graph network decoder.

FIG. 8 illustrates an example computer system.

### DESCRIPTION OF EXAMPLE EMBODIMENTS

Neural decoders were shown to improve the performance of message passing algorithms for decoding error correcting codes and outperform classical message passing techniques for short BCH codes. The embodiments disclosed herein extend these results to much larger families of algebraic block codes, by performing message passing with graph neural networks and hypernetworks. The parameters of the sub-network at each variable-node in the Tanner graph are obtained from a hypernetwork that receives the absolute values of the current message as input. To add stability, the embodiments disclosed herein employ a simplified version of the arctanh activation that is based on a high order Taylor approximation of this activation function. The embodiments disclosed herein further demonstrate how hypernetworks can be applied to decode polar codes by employing a new formalization of the polar belief propagation decoding scheme. The experimental results show that for a large number of algebraic block codes, from diverse families of codes (BCH, LDPC, Polar), the decoding obtained with the embodiments disclosed herein outperforms the vanilla belief propagation method as well as other learning techniques from the literature. The embodiments disclosed herein demonstrate that the proposed method improves the previous results of neural polar decoders and achieves, for large SNRs, the same bit-error-rate performances as the successive list cancellation method, which is known to be better than any belief propagation decoders and very close to the maximum likelihood decoder.

In particular embodiments, a computing system may input an encoded message with noise to a neural-networks model. In particular embodiments, the neural-networks model may comprise a first layer of nodes and a second layer of nodes. Each node may be associated with at least one weight and a hyper-network node. In particular embodiments, the computing system may update the weights associated with the first layer of nodes by processing the encoded message with noise using the hyper-network nodes associated with the first layer of nodes. The computing system may then generate a first set of outputs by processing the encoded message with noise using the variable first layer of nodes and their respective updated weights. In particular embodiments, the computing system may then update the weights associated with the second layer of nodes by processing the first set of outputs using the hyper-network nodes associated with the second layer of nodes. The computing system may further generate a decoded message without noise using the neural-networks model. In particular embodiments, the generation may comprise using at least the first set of outputs and the second layer of nodes and their respective updated weights.

In particular embodiments, a computing system may input an encoded message with noise to a neural-networks model. In particular embodiments, the neural-networks model may comprise a variable layer of nodes and a check layer of nodes. Each node may be associated with at least one weight and a hyper-network node. In particular embodiments, the computing system may update the weights associated with the variable layer of nodes by processing the encoded message using the hyper-network nodes associated with the variable layer of nodes. The computing system may then generate a first set of outputs by processing the encoded message using the variable layer of nodes and their respective updated weights. In particular embodiments, the computing system may then update the weights associated with the check layer of nodes by processing the first set of outputs using the hyper-network nodes associated with the check layer of nodes. The computing system may further generate a decoded message without noise using the neural-networks model. In particular embodiments, the generation may comprise using at least the first set of outputs and the check layer of nodes and their respective updated weights. Decoding small algebraic block codes is an open problem and learning techniques have recently been introduced to this field. While the first networks were fully connected (FC) networks, these were replaced with recurrent neural networks (RNNs), which follow the steps of the belief propagation (BP) algorithm. These RNN solutions weight the messages that are being passed as part of the BP method with fixed learnable weights. The development of neural decoders for error correcting codes has been evolving along multiple axes. In one axis, learnable parameters have been introduced to increasingly sophisticated decoding methods. Polar codes, for example, benefit from structural properties that require more dedicated message passing methods than conventional LDPC decoders. A second axis is that of the role of learnable parameters. Initially, weights were introduced to existing computations. Subsequently, neural networks replaced some of the computations and generalized these. The introduction of hypernetworks, in which the weights of the network vary based on the input, added a new layer of adaptivity.

The embodiments disclosed herein add compute to the message passing iterations, by turning the message graph into a graph neural network, in which one type of nodes, called variable nodes, processes the incoming messages with a FC network g. Since the space of possible messages is large and its underlying structure random, training such a network is challenging. Instead, the embodiments disclosed herein make this network adaptive, by training a second network ƒ to predict the weights 61₉ of network g. The embodiments disclosed herein further address the specialized belief propagation decoder for polar codes, which makes use of the structural properties of these codes. The embodiments disclosed herein introduce a graph neural network decoder whose architecture varies, as well as it weights. This allows the decoder disclosed herein to better adapt to the input signal.

This “hypernetwork” scheme, in which one network predicts the weights of another, allows one to control the capacity, e.g., one can have a different network per node or per group of nodes. Since the nodes in the decoding graph are naturally stratified and since a per-node capacity is too high for this problem, the second option is selected. Training such a hypernetwork may still fail to produce the desired results, without applying two additional modifications. The first modification is to apply an absolute value to the input of network ƒ, thus allowing it to focus on the confidence in each message rather than on the content of the messages. In other words, the computing system may apply an absolute value of the encoded message. In particular embodiments, each hyper-network may be associated with an activation function. The activation function may comprise one or more of a tanh activation function, an arctanh activation function, or a Taylor approximation of an arctanh activation function. The second modification is to replace the arctanh activation function that is employed by the check nodes with a high order Taylor approximation of this function, which may avoid its asymptotes.

When applying learning solutions to algebraic block codes, the exponential size of the input space may be mitigated by ensuring that certain symmetry conditions are met. In this case, it may be sufficient to train the network on a noisy version of the zero codeword. The embodiments disclosed herein show that the architecture of the hypernetwork employed is selected such that these conditions are met.

Applied to a wide variety of codes, the embodiments disclosed herein outperform the current learning-based solutions, as well as the classical BP method, both for a finite number of iterations and at convergence of the message passing iterations. The embodiments disclosed herein also demonstrate the experimental results on polar codes of various block sizes and show improvement in all SNRs over the baseline methods. Furthermore, for large SNRs, the embodiments disclosed herein match the performance of the successive list cancellation decoder.

The embodiments disclosed herein consider codes with a block size of n bits. It may be defined by a binary generator matrix G of size k×n and a binary parity check matrix H of size (n−k)×n. In particular embodiments, the computing system may apply a binary generator matrix and a binary parity check matrix to the encoded message with noise.

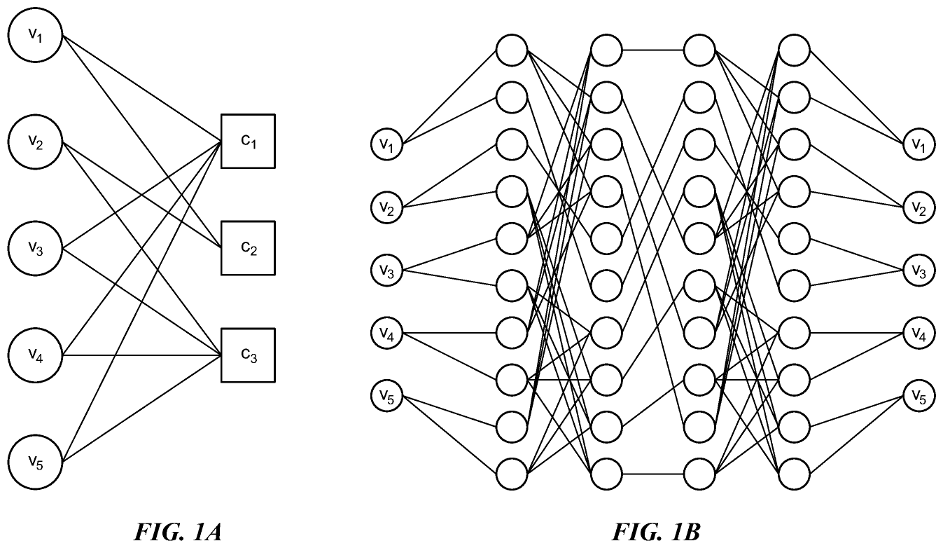

FIG. 1A illustrates an example Tanner graph for a linear block code. In particular embodiments, the parity check matrix may entail a Tanner graph, which may have n variable nodes and (n K) check nodes, as illustrated in FIG. 1A. In FIG. 1A, n=5, k=2 and dᵥ=2. The edges of the graph may correspond to the values in each column of the matrix H. For notational convenience, the embodiments disclosed herein assume that the degree of each variable node in the Tanner graph, i.e., the sum of each column of H, has a fixed value 01,

FIG. 1B illustrates an example Trellis graph corresponding to FIG. 1A. The Tanner graph may be unrolled into a Trellis graph. This graph may start with n variable nodes and may be then composed of two types of columns, variable columns and check columns. Variable columns may consist of variable processing units and check columns may consist of check processing units. dᵥ variable processing units may be associate with each received bit, and the number of processing units in the variable column may be, therefore, E=dᵥn. The check processing units may be also directly linked to the edges of the Tanner graph, where each parity check may correspond to a row of H. Therefore, the check columns may also have E processing units each. The Trellis graph ends with an output layer of n variable nodes. FIG. 1B illustrates an example Trellis graph with two iterations.

Message passing algorithms may operate on the Trellis graph. The messages may propagate from variable columns to check columns and from check columns to variable columns, in an iterative manner. The leftmost layer may correspond to a vector of log likelihood ratios (LLR) l∈ [symbol] ⁿ: of the input bits:

$${l}_{v} = log \frac{P r ( {c}_{v} = 1 \text{\textbar} {y}_{v} )}{P r ( {c}_{v} = 0 \text{\textbar} {y}_{v} )} ,$$

where υ∈[n] is an index and y₄ is the channel output for the corresponding bit cᵥ, which the embodiments disclosed herein may recover.

Let x^{j} be the vector of messages that a column in the Trellis graph propagates to the next column. At the first round of message passing j=1, and similarly to other cases where j is odd, a variable node type of computation may be performed, in which the messages may be added:

$${x}_{e}^{j} = {x}_{( c , v )}^{j} = {l}_{v} + {\sum }_{{e}^{1} ∈ N ( v ) \{ ( c , v ) \}} {x}_{{e}^{1}}^{j - 1} , \qquad ( 1 )$$

where each variable node is indexed the edge e=(c, v) on the Tanner graph and N(υ)={(c, υ)|H(c, υ)=1}, i.e, the set of all edges in which v participates. By definition x⁰=0 and when j=1 the messages are directly determined by the vector 1.

For even j, the check layer may perform the following computations:

$${x}_{e}^{j} = {x}_{( c , v )}^{j} = arctanh ( {\prod }_{{e}^{′} ∈ N ( c ) \{ ( c , v ) \}} tanh ( \frac{{x}_{{e}^{1}}^{j - 1}}{2} ) ) , \qquad ( 2 )$$

where N(c)={(c, υ)|H(c, υ)=1} is the set of edges in the Tanner graph in which row c of the parity check matrix H participates.

In particular embodiments, the tanh activation may be moved to the variable node processing units. In addition, a set of learned weights wₑ may be added. Note that the learned weights may be shared across all iterations j of the Trellis graph.

$$\begin{matrix}\begin{matrix}{x}_{e}^{j} = {x}_{( c , v )}^{j} = tanh ( \frac{1}{2} ( {l}_{v} + {\sum }_{{e}^{′} ∈ N ( v ) \backslash \{ ( c , v \}} {w}_{{e}^{′}} {x}_{{e}^{′}}^{j - 1} ) ) , & if j is odd\end{matrix} & ( 3 ) \\ \begin{matrix}{x}_{e}^{j} = {x}_{( c , v )}^{j} = 2 acrtanh ( {\prod }_{{e}^{′} ∈ N ( c ) \backslash \{ ( c , v \}} {x}_{{e}^{′}}^{j - 1} ) , & if j is even\end{matrix} & ( 4 )\end{matrix}$$

As mentioned, the computation graph may alternate between variable columns and check columns, with L layers of each type. The final layer may marginalize the messages from the last check layer with the logistic (sigmoid) activation function σ, and output n bits. The with bit output at layer 2L+1, in the weighted version, may be given by:

oᵥ=σ(lᵥ+Σ_{e∈N(v)}(w̅ₑ̅xₑ^{2l}) (5)

where w̅ₑ̅ is a second set of learnable weights.

The embodiments disclosed herein further add learned components into the message passing algorithm. Specifically, the embodiments disclosed herein replace Eq. (3) (odd j) with the following equation:

xₑ^{j}=x_{(c,v)}^{j}=g(lᵥ,x_{N(v,\c)}^{j-1}θ_{g}^{j),} (6)

where x_{N(v,c)}^{j} is a vector of length dᵥ−1 that contains the elements of x^{j} that correspond to the indices N(v)\{(c,v)} and θ_{g}^{j} has the weights of network g at iteration j.

In order to make g adaptive to the current input messages at every variable node, the embodiments disclosed herein employ a hypernetwork scheme and use a network ƒ to determine its weights.

θ_{g}^{j}=ƒ(|x^{j-1}|,θ_{ƒ}), (7)

where θ_{ƒ} are the learned weights of network ƒ. Note that g is fixed to all variable nodes at the same column. The embodiments disclosed herein have also experimented with different weights per variable (further conditioning g on the specific messages x_{N(v,\c)}^{j-1} for the variable with index e=(v,c)). However, the added capacity seems detrimental.

The adaptive nature of the hypernetwork allows the variable computation, for example to neglect part of the inputs of g, in case the input message l contains errors.

Note that the messages x^{j-1} are passed to ƒ in absolute value (Eq. (7)). The absolute value of the messages may be sometimes seen as measure for the correctness, and the sign of the message as the value (zero or one) of the corresponding bit. The embodiments disclosed herein remove the signs to make the network ƒ focus on the correctness of the message and not the information bits.

The architecture of both ƒ and g may not contain bias terms and employ tanh activations. The network g may have p layers, i.e. θ_{g}=(W₁, . . . , Wₚ), for some weight matrices Wᵢ. The network ƒ may end with p linear projections, each corresponding to one of the layers of network g. As noted above, if a set of symmetry conditions are met, then it may be sufficient to learn to correct the zero codeword.

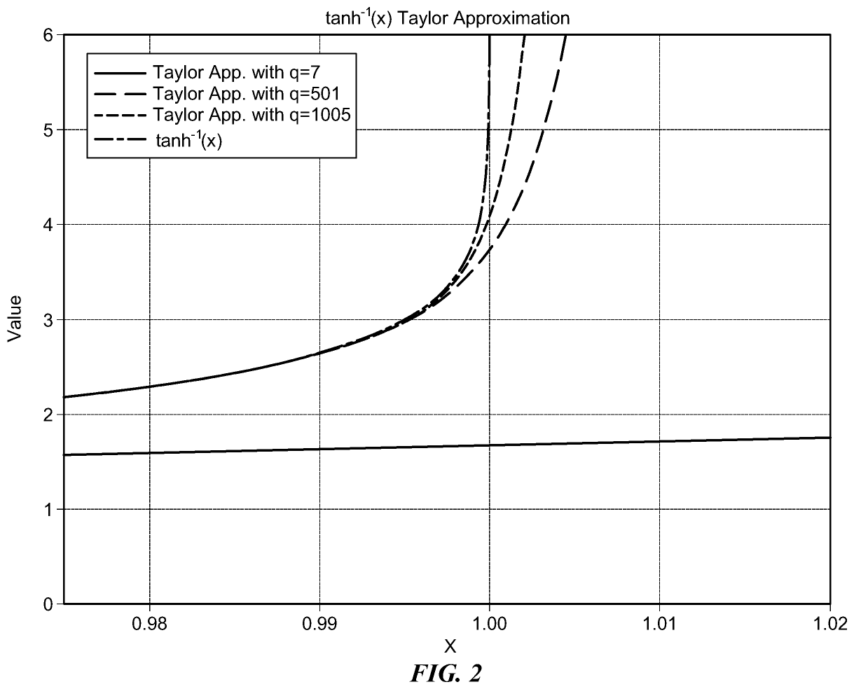

FIG. 2 illustrates an example Taylor approximation of the arctanh activation function. Another modification is being done to the columns of the check variables in the Trellis graph. For even values of j, the embodiments disclosed herein employ the following computation, instead of Eq. (4).

$${x}_{e}^{j} = {x}_{( c , v )}^{j} = 2 {\sum }_{m = 0}^{q} \frac{1}{2 m + 1} {( {\prod }_{e ∈ N ( c ) \backslash \{ \{ c , v ) \}} {x}_{e}^{j - 1} )}^{2 m + 1} \qquad ( 8 )$$

in which arctanh is replaced with its Taylor approximation of degree q. The approximation is employed as a way to stabilize the training process. The arctanh activation, has asymptotes in x=1, −1, and training with it often explodes. Its Taylor approximation may be a well-behaved polynomial as illustrated in FIG. 2.

In addition to observing the final output of the network, as given in Eq. (5), the embodiments disclosed herein consider the following marginalization for each iteration where j is odd:

$${o}_{v}^{j} = σ ( {l}_{v} + {Σ}_{e ∈ N ( v ) \overline{{w}_{e}}} {x}_{e}^{j} ) .$$

The embodiments disclosed herein may employ the cross entropy loss function, which considers the error after every check node iteration out of the L iterations:

$$ℒ = - \frac{1}{n} {\sum }_{h = 0}^{L} {\sum }_{v = 1}^{n} {c}_{v} log ( {o}_{v}^{2 h + 1} ) + ( 1 - {c}_{v} ) log ( 1 - {o}_{v}^{2 h + 1} ) , \qquad ( 9 )$$

where cᵥ is the ground truth bit. This loss may simplify, when learning the zero codeword, to

$$- \frac{1}{n} {\sum }_{h = 0}^{L} {\sum }_{v = 1}^{n} log ( 1 - {o}_{v}^{2 h + 1} ) .$$

The learning rate was 1e-4 for all type of codes, and the Adam optimizer (i.e., a conventional optimization algorithm) may be used for training. The decoding network may have ten layers which simulates L=5 iterations of a modified BP algorithm.

For block codes that maintain certain symmetry conditions, the decoding error may be independent of the transmitted codeword. A direct implication may be that the embodiments disclosed herein may train a network to decode only the zero codeword. Otherwise, training may need to be performed for all 2^{k} words. Note that training with the zero codeword should give the same results as training with all 2^{k} words.

There may be two symmetry conditions.
1. For a check node with index (c, v) at iteration j and for any vector b∈{0,1}^{d}^{ᵥ}⁻¹

ϕ(b^{T}x_{N(v,\c)}^{j-1})=(Π₁^{K})ϕ(x_{N(\v,c)}^{j-1}), (10)

where x_{N(\v,c)} is a vector of length dᵥ−1 that contains the elements of x^{j} that correspond to the indices N(c)\{(c,v)} and ϕ is the activation function used, e.g., arctanh or the truncated version of it.
2. For a variable node with index (c, v) at iteration j, which performs computation ψ

ψ(−lᵥ,−x_{N(v,\c)}^{j-1})=−ψ(lᵥ,x_{N(v,\c)}^{j-1}), (11)

In the embodiments disclosed herein, ψ is a FC neural network (g) with tanh activations and no bias terms.

The embodiments disclosed herein, by design, may maintain the symmetry condition on both the variable and the check nodes. This may be verified in the following lemmas.

Lemma 1. Assuming that the check node calculation is given by Eq. (8) then the proposed architecture satisfies the first symmetry condition.

Proof In the embodiments disclosed herein the activation function is Taylor approximation of arctanh. Let the input message at j be x_{N(\v, c)}^{j}=(x₁^{j}, . . . , x_{K}^{j}) for K=dᵥ−1. The embodiments disclosed herein can verify that:

$${x}^{j} ( {b}_{1} {x}_{1}^{j - 1} , … , {b}_{K} {x}_{K}^{j - 1} ) = 2 {\sum }_{m = 0}^{q} \frac{1}{2 m + 1} {( {\prod }_{k = 1}^{K} {b}_{k} {x}_{k}^{j - 1} )}^{2 m + 1} = 2 ( {\prod }_{k = 1}^{K} {b}_{k} ) {\sum }_{m = 0}^{q} \frac{1}{2 m + 1} {( {\prod }_{k = 1}^{K} {x}_{k}^{j - 1} )}^{2 m + 1} = ( {\prod }_{k = 1}^{K} {b}_{k} ) {x}_{j} ( {x}_{1}^{j - 1} , … , {x}_{K}^{j - 1} )$$

where the second equality holds since 2m+1 is odd.

Lemma 2. Assuming that the variable node calculation is given by Eq. (6) and Eq. (7), g does not contain bias terms and employs the tanh activation, then the proposed architecture satisfies the variable symmetry condition.

Proof Let K=dᵥ−1 and x_{N(v,\c)}^{j}=(x₁^{j}, . . . , x_{K}^{j}). In the embodiments disclosed herein for any odd j 0, ψ is given as

g(lᵥ,x₁^{j-1}, . . . , x_{K}^{j-1},θ_{g}^{j})=tanh(Wₚ^{T} tanh(W₂^{T} tanh(W₁^{T}(lᵥ,x₁^{j-1}, . . . , x_{K}^{j-1})))) (12)

where p is the number of layers and the weights W₁, . . . , Wₚ constitute θ_{g}^{j}=ƒ(|x^{j-1}|,θ_{ƒ}).

For real valued weights θ_{g}^{lhs} and θ_{g}^{rhs}, since tanh(x) is an odd function for any real value input, if θ_{g}^{lhs}=θ_{g}^{rhs} then g(lᵥ,x₁^{j-1}, . . . , x_{K}^{j-1},θ_{g}^{lhs})=−g(−lᵥ,−x₁^{j-1}, . . . , −x_{K}^{j-1},θ_{g}^{rhs}). In the embodiments disclosed herein, θ_{g}^{lhs}=ƒ(|x^{j-1}|,θ_{ƒ})=ƒ(|−x^{j-1}|,θ_{ƒ}=θ_{g}^{rhs}).

The embodiments disclosed herein may further modify the aforementioned model with the following updates for Eq. (6) and Eq. (7), respectively. For odd j:

xₑ^{j}=x_{(c,v)}^{j}=g(lᵥ,c·x⁰+(1−c)·x_{N(v,\c)}^{j-1},θ_{g}^{j),} (13)

θ_{g}^{j}=ƒ(|c·x⁰+(1−c)·x^{j-1}|,θ_{ƒ}) (14)

where x⁰ is the output of one iteration from Eq. (3), and c is the damping factor which is learned during training.

For an even j the embodiments disclosed herein either use Eq. (8) (Taylor approximated arctanh), or consider the conventional arctanh activation, as in Eq. (4).

For polar codes, the embodiments disclosed herein consider a (N, K) polar code, where N is the block size and K is the number of information bits. The polar factor graph may have (n+1)N nodes,

$$\frac{N}{2} {log}_{2} N$$

blocks and n=log₂ N stages. Each node in the factor graph may index by tuple (i, j) where 1≤i≤n+1, 1≤j≤N. The rightmost nodes (n+1, ⋅) may be the noisy input from the channel yⱼ, and the leftmost nodes (1, ⋅) may be the source data bits uⱼ. The polar belief propagation decoder may use two types of messages in order to estimate the log likelihood ratios (LLRs): left and right messages L_{i,j}^{(T)}, R_{i,j}^{(t)}, where t is the number of the BP iteration. The left messages are initialized at t=0 with the input log likelihood ratio:

$${L}_{n + 1 , j}^{( 1 )} = \frac{P ( {y}_{j} \text{\textbar} {x}_{j} = 0 )}{P ( {y}_{j} \text{\textbar} {x}_{j} = 1 )} \qquad ( 15 )$$

The right messages are initialized with the information bit location:

$${R}_{n + 1 , j}^{( 1 )} + \frac{P ( {u}_{j} = 0 )}{P ( {u}_{j} = 1 )} = \{ \begin{matrix}1 j is an information bit \\ ∞ else\end{matrix} \qquad ( 16 )$$

The other messages L_{i,j}⁽¹⁾, R_{i,j}⁽¹⁾ are set to 1. The iterative belief propagation equation for the messages are:

L_{i,j}^{(t)}=g(L_{i+1,j}^{(t-1)},L_{i+1,j+N}_{ᵢ}^{(t-1)}+R_{i,j+N}_{ᵢ}^{(t)}),

L_{i,j+N}_{ᵢ}^{(t)}=g(R_{i,j}^{(t)},L_{i+1,j}^{(t-1)})+L_{i+1,j+N}_{ᵢ}^{(t-1)} (17)

R_{i+1,j}^{(t)}=g(R_{i,j}^{(t)},L(_{i+1,j+N}_{ᵢ}^{(t-1)}+R_{i,j+N}_{ᵢ}^{(t)})

R_{i+1,j+N}_{ᵢ}^{(t)}=g(L_{i,j}^{(t)},L_{i+1,j}^{(t-1)})+R_{i,j+N}_{ᵢ}^{(t)}

where Ni=N/2ⁱ and the function g is:

$$g ( x , y ) = ln \frac{1 + xy}{x + y} . \qquad ( 18 )$$

Alternatively, g may be replaced by the min-sum approximation:

g(x,y)≈sign(x)·sign(y)·min(|x|,|y|) (19)

The final estimation is a hard slicer on the left messages L_{1,j}^{(T)} where T is the last iteration:

$${\hat{u}}_{j}^{N} \{ \begin{matrix}0 , {L}_{1 , j}^{( T )} \geq 0 , \\ 1 , {L}_{1 , j}^{( T )} < 0\end{matrix} \qquad ( 20 )$$

A conventional neural polar decoder may unfold the polar factor graph and assign weights in each edge. The update equation may be taking the form:

L_{i,j}^{(t)}=α_{i,j+N}_{ᵢ}^{(t)}·g(L_{i+1,j}^{(t-1)},L_{i+1,j+N}^{(t-i)}+R_{i,j+N}_{ᵢ}^{(t)}),

L_{i,j+N}_{ᵢ}^{(t)=α}_{i,j+N}_{ᵢ}^{(t)}·g(R_{i,j}^{(t)},L_{i+1,j}^{(t-1))+L}_{i+1,j+N}_{_{i′}}^{(t-)} (21)

R_{i,j+N}_{ᵢ}^{(t)}=β_{i+1,j}^{(t)}·g(R_{i,j}^{(t)},L_{i+1,j+N}^{(t-)}+R_{i,j+N}_{ᵢ}^{(t)}),

R_{i+1,j+N}_{ᵢ}^{(t)=β}_{i+1,j+N}_{ᵢ}^{(t)}·g(R_{i,j}^{(t)},L_{i+1,j}^{(t-1)}+R_{i,j+N}_{ᵢ}^{(t)}

where α_{i,j}^{(t)} and β_{i,j}^{(t)} are learnable parameters for the left message L_{i,j}^{(t)} and right message R_{i,j}^{(t)} respectively. The output of the neural decoder may be defined by:

oⱼ=σ(L_{1,j}^{(T))} (22)

where σ is the sigmoid activation. The loss function may be the cross entropy between the transmitted codeword and the network output:

$$L ( o , u ) = - \frac{1}{N} {\sum }_{j = 1}^{N} {u}_{j} log ( {o}_{j} ) + ( 1 - {u}_{j} ) log ( 1 - {o}_{j} ) \qquad ( 23 )$$

A conventional recurrent neural polar decoder may share the weights among different iterations: α_{i,j}^{(t)=α}ᵢⱼ and β_{i,j}^{(t)=β}_{i,j}. The corresponding BER-SNR curve may achieve comparable results to training the neural decoder without tying the weights from different iterations.

The embodiments disclosed herein use a new structure-adaptive hypernetwork architecture for decoding polar codes. The new architecture adds three major modifications. First, the embodiments disclosed herein incorporate a graph neural network that uses the unique structure of the polar code. Second, the embodiments disclosed herein add a gating mechanism to the activations of the (hyper) graph network, in order to adapt the architecture itself according to the input. Third, the embodiments disclosed herein add a damping factor c to the updating equations in order to improve the training stability of the proposed method. In particular embodiments, each activation function may be associated with a damping factor.

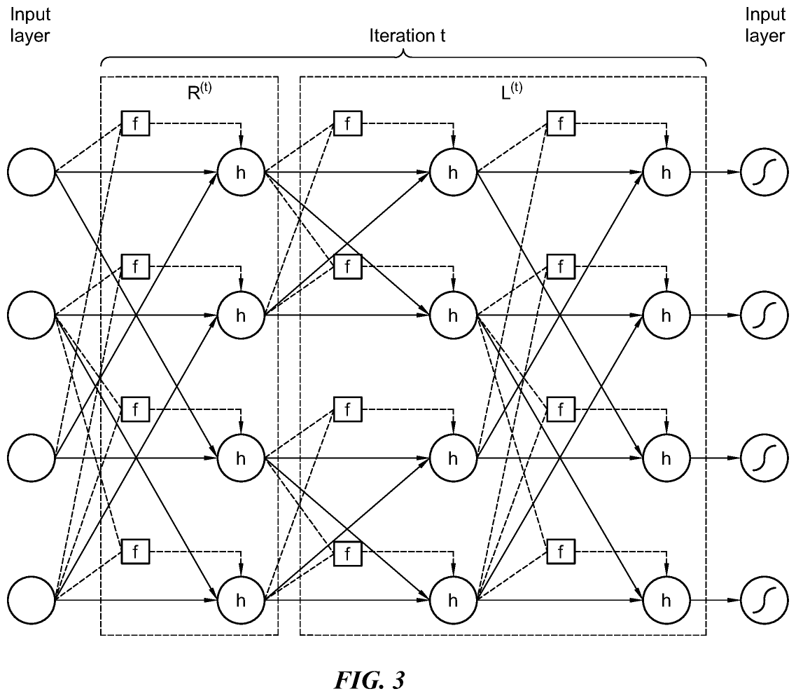

FIG. 3 illustrates an example structure-adaptive hypernetwork architecture for decoding polar codes. In FIG. 3, the polar code has N=4 and T=1. The connections of the graph hypernetwork are denoted by the dashed lines. ƒ is the function that determines the weights of the graph nodes h. To reduce clutter, the damping factors are not shown in FIG. 3. At each iteration t, the embodiments disclosed herein employ the hyper-network ƒ.

θ_{i,j}^{(t)},σ_{i,j}^{(t)}=ƒ(|L_{i+1,j}^{(t-1)}|,|L_{i+1+N}_{ᵢ}^{(t-1)}R_{i,j+Ni}^{(t)}|)

θ_{i,j+N}_{ᵢ}^{(t)},σ_{i,j+N}_{ᵢ}^{(t)}=ƒ(|R_{i,j}^{(t)|,|L}_{i+1,j}^{(t-1)}|) (24)

θ_{i+1,j}^{(t)},σ_{i+1,j}^{(t)}=ƒ(|R_{i,j}^{(t)}|,|L_{i+1,j}^{(t-1)}+R_{i,j+N}_{ᵢ}^{(t)}|)

θ_{i+1,j+N}_{ᵢ}^{(t)},σ_{i+1,j+N}_{ᵢ}^{(t)}=ƒ(|R_{i,j}^{(t)}|,|L_{i+1,j}^{(t-1)}|)

where ƒ is a neural network that determines the weights and gating activation of network h. In particular embodiments, updating the weights associated with the variable layer of nodes by processing the encoded message with noise using the hyper-network nodes associated with the variable layer of nodes may be based on the activation functions. Updating the weights associated with the check layer of nodes by processing the first set of outputs using the hyper-network nodes associated with the check layer of nodes may be also based on the activation functions. The network ƒ may have four layers with tanh activations. Note that the inputs to the function ƒ may be in absolute value. The embodiments disclosed herein use the absolute value of the input messages in order to focus on the correctness of the messages and not the bit information.

In particular embodiments, updating the weights associated with the variable layer of nodes by processing the encoded message with noise using the hyper-network nodes associated with the variable layer of nodes may be based on the activation functions and their respective damping factors. Updating the weights associated with the check layer of nodes by processing the first set of outputs using the hyper-network nodes associated with the check layer of nodes may be also based on the activation functions and their respective damping factors. Furthermore, the embodiments disclosed herein replace the updating Eq. 21 with the following equations:

L_{i,j}^{(t)}=(1−c)·h(L_{i+1,j}^{(t-1)},L_{i+1,j+N}_{ᵢ}₊^{(t-1)}+R_{i,j+N}_{ᵢ}^{(t-1)},θ_{i,j}^{(t)},σi,j^{(t))}+c·α_{i,j}^{(t)}·g(L_{i+1,j}^{(t-1)},L_{i+1,j+N}_{ᵢ}^{(t-)}+R_{i,j+N}_{ᵢ}^{(t)}),

L_{i,j+N}_{ᵢ}^{(t)}=(1−c)·h(R_{i,j}^{(t)},L_{i+1,j}^{(t+1)},θ_{i,j+Ni}^{(t)},σ_{i,j+N}_{ᵢ}^{(t)})+c·α_{i,j}^{(t)}g(L_{i,j}^{(t-1)},L_{i+1,j+Ni}^{(t-1)},R_{i+1,j}^{(t)}=(1−c)·h(R_{i,j}^{(t)},L_{i+1,j+N}_{ᵢ}^{(t-1)},R_{i,j+N}_{ᵢ}^{(t)},θ_{i+1,j}^{(t)},σ_{i+1,j}^{(t)})+c·β_{i+1,j}^{(t)}·g(R_{i,j}^{(t)},L_{i+1,j}^{(t-1)})+R_{i,j+N}_{ᵢ}^{(t)}),

R_{i+1,j+N}_{ᵢ}^{(t)}=(1−c)·h(R_{i,j}^{(t)},L_{i+1,j}^{(t-1)},θ_{i+1,j+N}_{ᵢ}^{(t)},σ_{i+1,j+N}_{ᵢ}^{(t)})+c·β_{i+1,j+N}_{ᵢ}^{(t)}·g(R_{i,j}^{(t)},L_{i+1,l}^{(t-1)})+R_{i,j+N}_{ᵢ}^{(t)}, (25)

where the damping factor c is a learnable parameter, initialized from uniform distribution [0, 1] and learned with clipping to the range of [0, 1] during the training. The network h may have two layers with tanh activations. Note that the weights of network h are determined by the network ƒ and the activations of each layer in h are multiplied by the gating σ_{i,j}^{(t)} from the network ƒ. The output layer and the loss function are the same as in Eq. (8) and Eq. (9) respectively.

The conditions of Lemma 2 hold for the case of polar codes as well and, therefore, the decoding error may be independent of the transmitted codeword, allowing training solely with noisy versions of the zero codeword.

The embodiments disclosed herein conduct two sets of experiments for evaluation. In particular embodiments, the encoded message with noise is based on one or more of Bose-Chaudhuri-Hocquenghem (BCH) code, low density parity check (LDPC) code, or polar code. In the first set of experiments, the embodiments disclosed herein train the proposed architecture with three classes of linear block codes: low density parity check (LDPC) codes, polar codes and Bose-Chaudhuri-Hocquenghem (BCH) codes.

In particular embodiments, the neural-networks model may be trained based on a plurality of training examples. Each training example may be generated as a zero codeword transmitted over an additive white Gaussian noise. In particular embodiments, each training example may be associated with a distinct signal-to-noise (SNR) value. For validation, the embodiments disclosed herein use the generator matrix G, in order to simulate valid codewords.

The hyperparameters for each family of codes are determined by practical considerations. For Polar codes, which are denser than LDPC codes, the embodiments disclosed herein use a batch size of 90 examples. The embodiments disclosed herein train with SNR values of 1 dB, 2 dB, . . . , 6 dB where from each SNR the embodiments disclosed herein present 15 examples per single batch. For BCH and LDPC codes, the embodiments disclosed herein train for SNR ranges of 1-8 dB (120 samples per batch). In the reported results, the test error up to an SNR of 6 dB, since evaluating the statistics for higher SNRs in a reliable way requires the evaluation of a large number of test samples (recall that in training, the embodiments disclosed herein only need to train on a noisy version of a single codeword). However, for BCH codes, the embodiments disclosed herein extend the tests to 8 dB in some cases.

In the first set of experiments, the order of the Taylor series of arctanh is set to q=1005. The network ƒ has four layers with 32 neurons at each layer. The network g has two layers with 16 neurons at each layer. For BCH codes, the embodiments disclosed herein also tested a deeper configuration in which the network ƒ has four layers with 128 neurons at each layer.

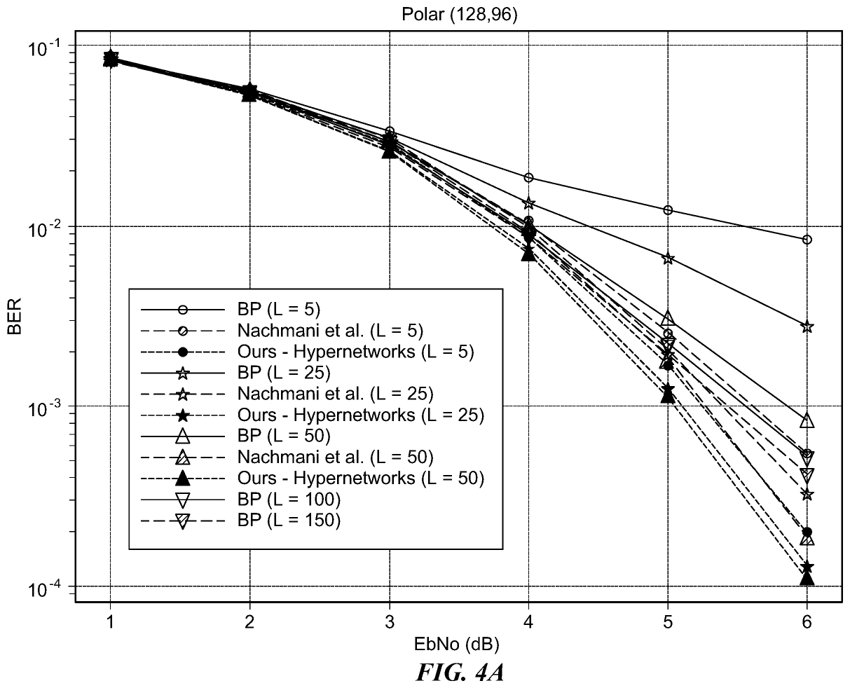

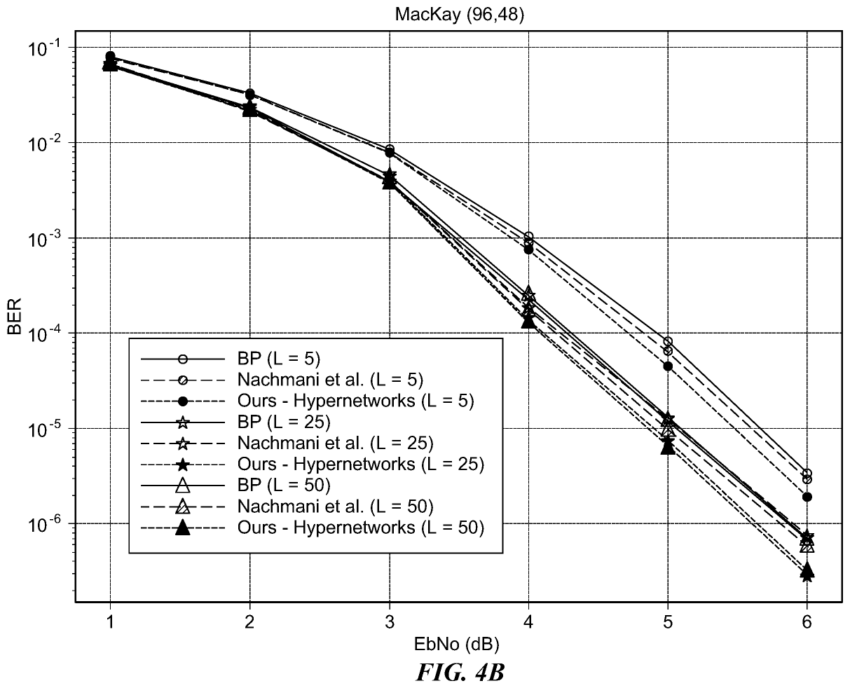

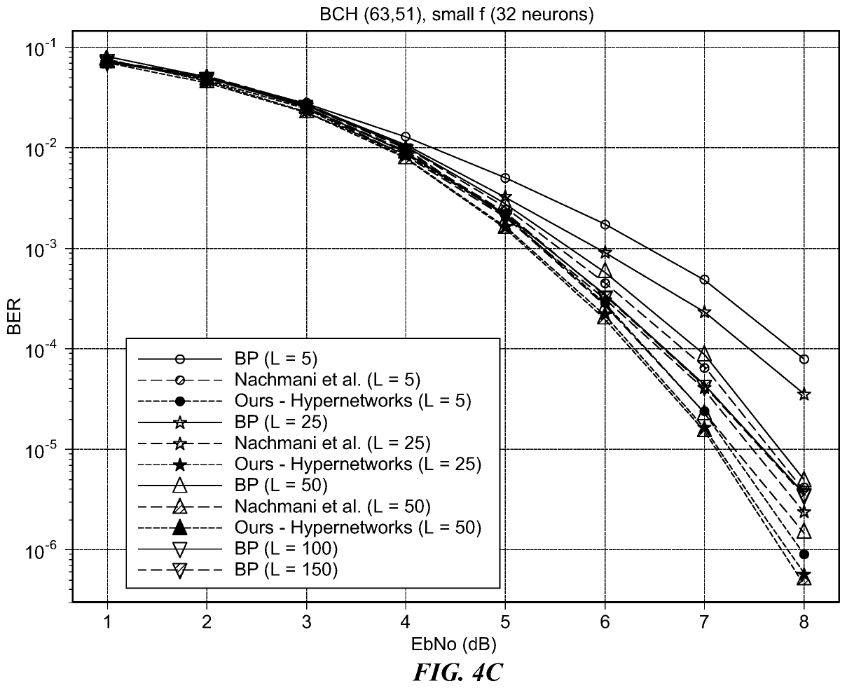

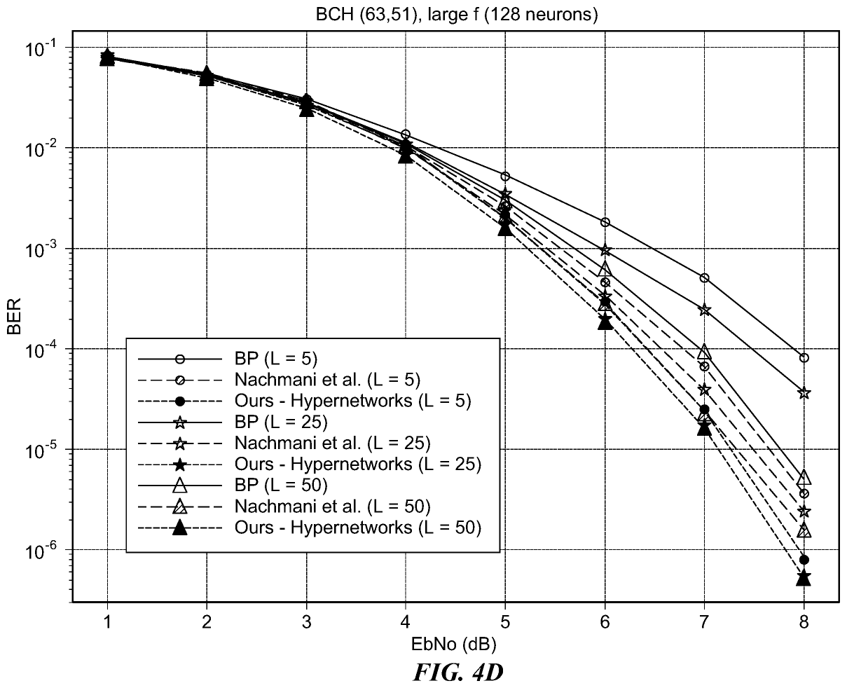

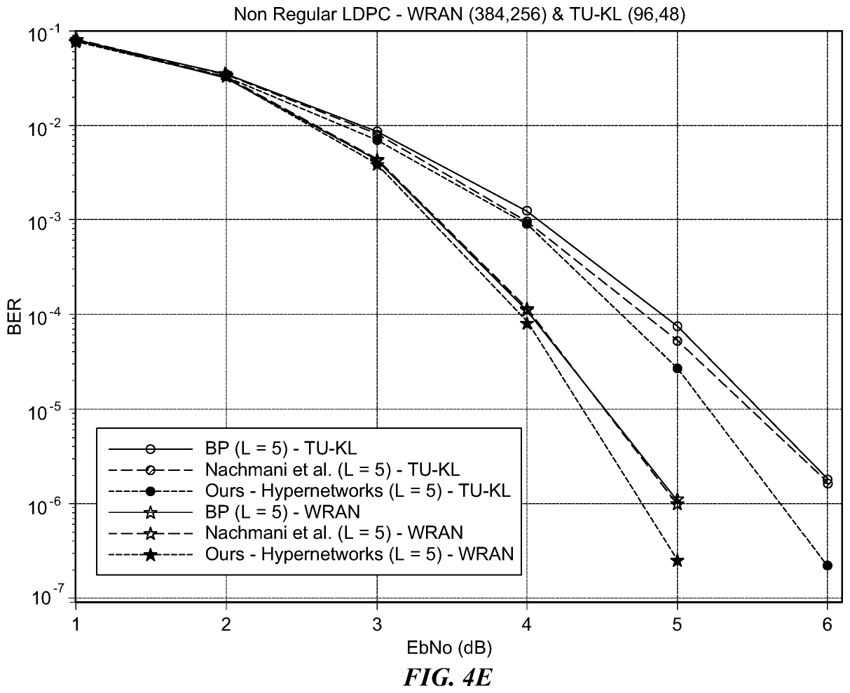

FIGS. 4A-4E illustrate example bit error rates (BER) for various values of SNR for various codes. The results are reported as bit error rates (BER) for different SNR values (dB). FIG. 4A illustrates example bit error rates (BER) for various values of SNR for Polar (128,96) code. FIG. 4B illustrates example bit error rates (BER) for various values of SNR for LDPC MacKay (96,48) code. FIG. 4C illustrates example bit error rates (BER) for various values of SNR for BCH (63,51) code. FIG. 4D illustrates example bit error rates (BER) for various values of SNR for BCH (63,51) with a deeper network ƒ. FIG. 4E illustrates example bit error rates (BER) for various values of SNR for large and non-regular LDPC including WRAN (384,256) and TU-KL (96,48) Table 1 lists results for more codes. As can be seen in FIG. 4A, for Polar (128,96) code with five iterations of BP the embodiments disclosed herein get an improvement of 0.48 dB over a conventional work. For LDPC MacKay (96,48) code, the embodiments disclosed herein get an improvement of 0.15 dB. For the BCH (63,51) with large ƒ the embodiments disclosed herein get an improvement of 0.45 dB and with small ƒ the embodiments disclosed herein get a similar improvement of 0.43 dB. Furthermore, for every number of iterations, the embodiments disclosed herein obtain better results than the conventional work. The disclosed method with 5 iteration achieved the same results as the conventional work with 50 iterations for BCH (63,51) and Polar (128,96) codes. Similar improvements were also observed for other BCH and Polar codes. As can be seen in FIG. 4E, the disclosed method improves the results, even in non-regular codes where the degree varies. Note that the embodiments disclosed herein learned just one hypernetwork g, which corresponds to the maximal degree and the embodiments disclosed herein discard irrelevant outputs for nodes with lower degrees. In Table 1 the embodiments disclosed herein present the negative natural logarithm of the BER. For the 15 block codes tested, the disclosed method gets better results than the BP and the conventional work. The results stay true for the convergence point of the algorithms, i.e., when the embodiments disclosed herein run the algorithms with 50 iterations.

TABLE 1
A comparison of the negative natural logarithm of Bit Error Rate (BER) for
three SNR values of our method with literature baselines. Higher is better.

| Method | | | | | | | | | | | |
|---|---|---|---|---|---|---|---|---|---|---|---|
| BP | | | A conventional work | | | Ours | | | Ours deeper f | | |
| 4 | 5 | 6 | 4 | 5 | 6 | 4 | 5 | 6 | 4 | 5 | 6 |

-after five iterations-

| | | | | | | | | | | | | |
|---|---|---|---|---|---|---|---|---|---|---|---|---|
| Polar (63, 32) | 3.52 | 4.04 | 4.48 | 4.14 | 5.32 | 6.67 | 4.25 | 5.49 | 7.02 | — | — | — |
| Polar (64, 48) | 4.15 | 4.68 | 5.31 | 4.77 | 6.12 | 7.84 | 4.91 | 6.48 | 8.41 | — | — | — |
| Polar (128, 64) | 3.38 | 3.80 | 4.15 | 3.73 | 4.78 | 5.87 | 3.89 | 5.18 | 6.94 | — | — | — |
| Polar (128, 86) | 3.80 | 4.19 | 4.62 | 4.37 | 5.71 | 7.19 | 4.57 | 6.18 | 8.27 | — | — | — |
| Polar (128, 96) | 3.99 | 4.41 | 4.78 | 4.56 | 5.98 | 7.53 | 4.73 | 6.39 | 8.57 | — | — | — |
| LDPC (49, 24) | 5.30 | 7.28 | 9.88 | 5.49 | 7.44 | 10.47 | 5.76 | 7.90 | 11.17 | — | — | — |
| LDPC (121, 60) | 4.82 | 7.21 | 10.87 | 5.12 | 7.97 | 12.22 | 5.22 | 8.29 | 13.00 | — | — | — |
| LDPC (121, 70) | 5.88 | 8.76 | 13.04 | 6.27 | 9.44 | 13.47 | 6.39 | 9.81 | 14.04 | — | — | — |
| LDPC (121, 80) | 6.66 | 9.82 | 13.98 | 6.97 | 10.47 | 14.86 | 6.95 | 10.68 | 15.80 | — | — | — |
| MacKay (96,48) | 6.84 | 9.40 | 12.57 | 7.04 | 9.67 | 12.75 | 7.19 | 10.02 | 13.16 | — | — | — |
| CCSDS (128, 64) | 6.55 | 9.65 | 13.78 | 6.82 | 10.15 | 13.96 | 6.99 | 10.57 | 15.27 | — | — | — |
| BCH (31, 16) | 4.63 | 5.88 | 7.60 | 4.74 | 6.25 | 8.00 | 5.05 | 6.64 | 8.80 | 4.96 | 6.63 | 8.80 |
| BCH (63, 36) | 3.72 | 4.65 | 5.66 | 3.94 | 5.27 | 6.97 | 3.96 | 5.35 | 7.20 | 4.00 | 5.42 | 7.34 |
| BCH (63, 45) | 4.08 | 4.96 | 6.07 | 4.37 | 5.78 | 7.67 | 4.48 | 6.07 | 8.45 | 4.41 | 5.91 | 7.91 |
| BCH (63, 51) | 4.34 | 5.29 | 6.35 | 4.54 | 5.98 | 7.73 | 4.64 | 6.08 | 8.16 | 4.67 | 6.19 | 8.22 |

-at convergence-

| | | | | | | | | | | | | |
|---|---|---|---|---|---|---|---|---|---|---|---|---|
| Polar (63, 32) | 4.26 | 5.38 | 6.50 | 4.22 | 5.59 | 7.30 | 4.59 | 6.10 | 7.69 | — | — | — |
| Polar (64, 48) | 4.74 | 5.94 | 7.42 | 4.70 | 5.93 | 7.55 | 4.92 | 6.44 | 8.39 | — | — | — |
| Polar (128, 64) | 4.10 | 5.11 | 6.15 | 4.19 | 5.79 | 7.88 | 4.52 | 6.12 | 8.25 | — | — | — |
| Polar (128, 86) | 4.49 | 5.65 | 6.97 | 4.58 | 6.31 | 8.65 | 4.95 | 6.84 | 9.28 | — | — | — |
| Polar (128, 96) | 4.61 | 5.79 | 7.08 | 4.63 | 6.31 | 8.54 | 4.94 | 6.76 | 9.09 | — | — | — |
| LDPC (49, 24) | 6.23 | 8.19 | 11.72 | 6.05 | 8.34 | 11.80 | 6.23 | 8.54 | 11.95 | — | — | — |
| MacKay (96, 48) | 8.15 | 11.29 | 14.29 | 8.66 | 11.52 | 14.32 | 8.90 | 11.97 | 14.94 | — | — | — |
| BCH (63, 36) | 4.03 | 5.42 | 7.26 | 4.15 | 5.73 | 7.88 | — | — | — | 4.29 | 5.91 | 8.01 |
| BCH (63, 45) | 4.36 | 5.55 | 7.26 | 4.49 | 6.01 | 8.20 | — | — | — | 4.64 | 6.27 | 8.51 |
| BCH (63, 51) | 4.58 | 5.82 | 7.42 | 4.64 | 6.21 | 8.21 | — | — | — | 4.80 | 6.44 | 8.58 |

To evaluate the contribution of the various components of the disclosed method, the embodiments disclosed herein ran an ablation analysis. The embodiments disclosed herein compare (i) our complete method, (ii) a method in which the parameters of g are fixed and g receives an additional input of |x^{j-1}|, (iii) a similar method where the number of hidden units in g was increased to have the same amount of parameters of ƒ and g combined, (iv) a method in which ƒ receives the x^{j-1} instead of the absolute value of it, (v) a variant of our method in which arctanh replaces its Taylor approximation, and (vi) a similar method to the previous one, in which gradient clipping is used to prevent explosion. The results reported in Table 2 demonstrate the advantage of our complete method. It may be observed that without hypernetwork and without the absolute value in Eq. (7), the results degrade below those of the conventional work. It may be also observed that for (ii), (iii) and (iv) the method reaches the same low-quality performance. For (v) and (vi), the training process explodes, and the performance is equal to a random guess. In (vi), the embodiments disclosed herein train the disclosed method while clipping the arctanh at multiple threshold values (TH=0.5, 1, 2, 4, 5, applied to both the positive and negative sides, multiple block codes BCH (31,16), BCH (63,45), BCH (63,51), LDPC (49,24), LDPC (121,80), POLAR (64,32), POLAR (128,96), L=5 iterations). In all cases, the training exploded, similarly to the no-threshold vanilla arctanh (v). In order to understand this, the values are observed when arctanh is applied at initialization for our method and for two conventional works. In these conventional works, which are initialized to mimic the vanilla BP, the activations are such that the maximal arctanh value at initialization is 3.45. However, in our case, in many of the units, the value explodes at infinity. Clipping does not help, since for any threshold value, the number of units that are above the threshold (and receive no gradient) is large. Since the embodiments disclosed herein employ hypernetworks, the weights θ_{g}^{j} of the network g are dynamically determined by the network ƒ and vary between samples, making it challenging to control the activations g produces. This highlights the critical importance of the Taylor approximation for the usage of hypernetworks in our setting. The table also shows that for most cases, the method of the conventional work slightly benefits from the usage of approximated arctanh.

TABLE 2
Ablation analysis. The negative natural logarithm
of BER results of our complete method are compared
with alternative methods. Higher is better.

| | Code | | | | | |
|---|---|---|---|---|---|---|
| | BCH (31, 16) | | BCH (63, 45) | | BCH (63, 51) | |
| Variant/SNR | 4 | 6 | 4 | 6 | 4 | 6 |
| (i) Complete method | 4.96 | 8.80 | 4.41 | 7.91 | 4.67 | 8.22 |
| (ii) No hypernetwork | 2.94 | 3.85 | 3.54 | 4.76 | 3.83 | 5.18 |
| (iii) No hypernetwork, | 2.94 | 3.85 | 3.54 | 4.76 | 3.83 | 5.18 |
| higher capacity | | | | | | |
| (iv) No abs in Eq. 7 | 2.86 | 3.99 | 3.55 | 4.77 | 3.84 | 5.20 |
| (v) Not truncating | 0.69 | 0.69 | 0.69 | 0.69 | 0.69 | 0.69 |
| arctanh | | | | | | |
| (vi) Gradient clipping | 0.69 | 0.69 | 0.69 | 0.69 | 0.69 | 0.69 |
| A conventional work | 4.74 | 8.00 | 3.97 | 7.10 | 4.54 | 7.73 |
| The conventional | 4.78 | 8.24 | 4.34 | 7.34 | 4.53 | 7.84 |
| work with | | | | | | |
| truncated arctanh | | | | | | |

In the second set of experiments, the embodiments disclosed herein train the proposed neural network for Polar codes with different block sizes N=128, 32. The number of iterations was T=5 for all block codes. The ƒ and h networks have 16 neurons in each layer, with tanh activations and without a bias term. The embodiments disclosed herein generate the training set of noisy variations of the zero codeword over an additive white Gaussian noise channel (AWGN). Each batch contains multiple examples from different Signal-To-Noise (SNR) values, specifically the embodiments disclosed herein use SNRs values of 1 dB, 2 dB, . . . , 6 dB. A batch size of 3600 and 1800 examples is used for N=32 and N=128, respectively. Learning rate at epoch k is set according to lrₖ=lr₀/(1+k·decay) where lr₀=0.99 and lr₀=2.5 for N=32 and N=128 respectively. The decay factor was 1e-4 and every epoch contain 125 batches. In all experiments, the embodiments disclosed herein use the feed-forward neural decoder. The BER calculation uses the information bits, i.e., the embodiments disclosed herein do not count the frozen bits when calculating the error rate performance.

The embodiments disclosed herein compare our method with the vanilla belief propagation algorithm, a conventional neural polar decoder and the successive list cancellation (SLC) method which does not employ learning and obtains state of the art performance.

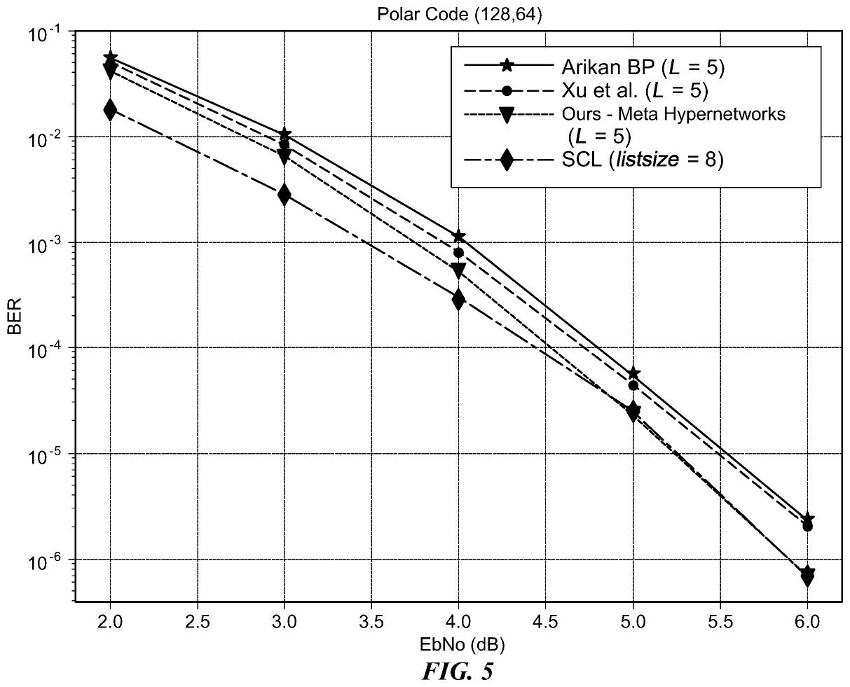

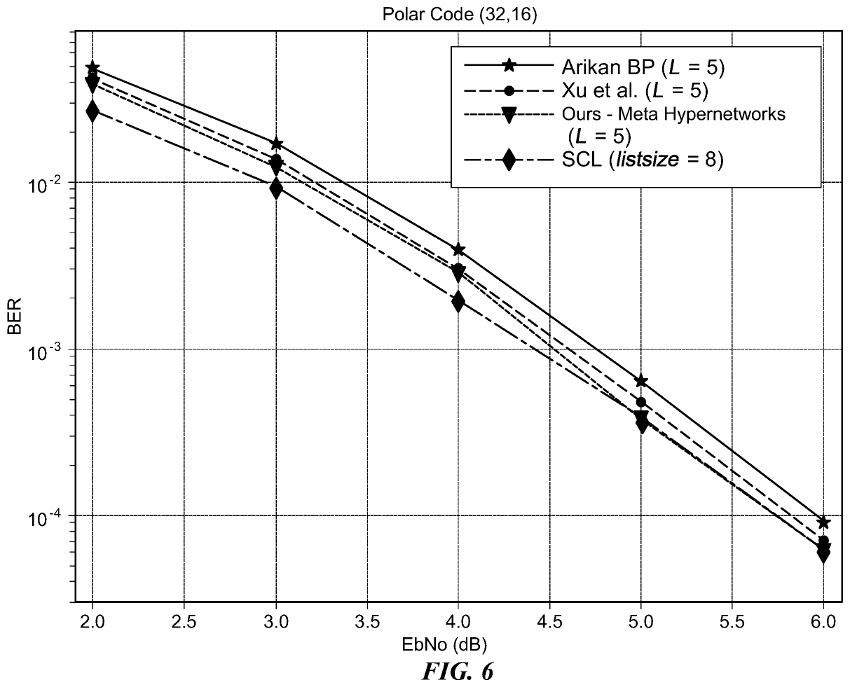

FIG. 5 illustrates example BER for Polar code (128,64). FIG. 6 illustrates example BER for Polar code (32,16). In FIG. 5 and FIG. 6, the embodiments disclosed herein present the Bit-Error-Rate versus EbN0 for N=128 and N=32, respectively. As can be seen, for N=32 our method's accuracy matches that of SLC for large SNRs (5 dB, 6 dB). Furthermore, for lower SNRs, our method improves the results of the conventional neural polar decoder by 0.1 dB. For large block, N=128, one can observe the same improvement in large SNRs value, where our method achieves the same performance as SLC, which is 0.4 dB better than the conventional neural polar decoder. For lower SNRs, our method improves the conventional neural polar decoder by 0.2 dB.

In order to evaluate the contribution of the various components of our method, the embodiments disclosed herein run an ablation analysis: (i) without the damping factor (ii) when using a fixed c=0.5 in Eq. (25) (iii) without the gating mechanism (iv) the complete method. The embodiments disclosed herein run the ablation study on a polar code with N=32.

Table 3 reports the results of the ablation analysis. As can be observed, the complete method, including the gating mechanism, outperforms a similar method without the damping factor (i) and without the gating mechanism (iii). Moreover, for training without the damping factor, the performance is equal to a random guess. Training with a fixed c=0.5 damping factor (ii) produces better results than c=0, however these results are worse than the complete method (iv).

TABLE 3
Ablation analysis for polar code (32, 16). The negative
natural logarithm of BER results of our complete method
are compared with several variants. Higher is better.

| | SNR[dB] | | | | |
|---|---|---|---|---|---|
| Variant | 1 | 2 | 3 | 4 | 5 |
| (i) No damping factor c = 0 | 0.73 | 0.73 | 0.74 | 0.74 | 0.75 |
| (ii) Unlearned damping c = 0.5 | 1.19 | 1.52 | 2.00 | 2.65 | 3.47 |
| (iii) No gating mechanism | 2.39 | 3.20 | 4.36 | 5.81 | 7.75 |
| (iv) Complete method | 2.42 | 3.25 | 4.40 | 5.85 | 7.87 |

The embodiments disclosed herein first present graph networks in which the weights are a function of the node's input and demonstrate that this architecture provides the adaptive computation that is required in the case of decoding block codes. Training networks in this domain can be challenging and the embodiments disclosed herein present a method to avoid gradient explosion that seems more effective, in this case, than gradient clipping. By carefully designing our networks, important symmetry conditions are met and the embodiments disclosed herein can train efficiently. The embodiments disclosed herein additionally present a hypernetwork scheme for decoding polar codes with a graph neural network. A novel gating mechanism is added in order to allow the network to further adapt to the input. The experimental results show our method goes far beyond the current literature on learning block codes and the embodiments disclosed herein present results for a large number of codes from multiple code families. The embodiments disclosed herein also demonstrate results on various polar codes and show that our method can achieve the same performance as successive list cancellation for large SNRs.

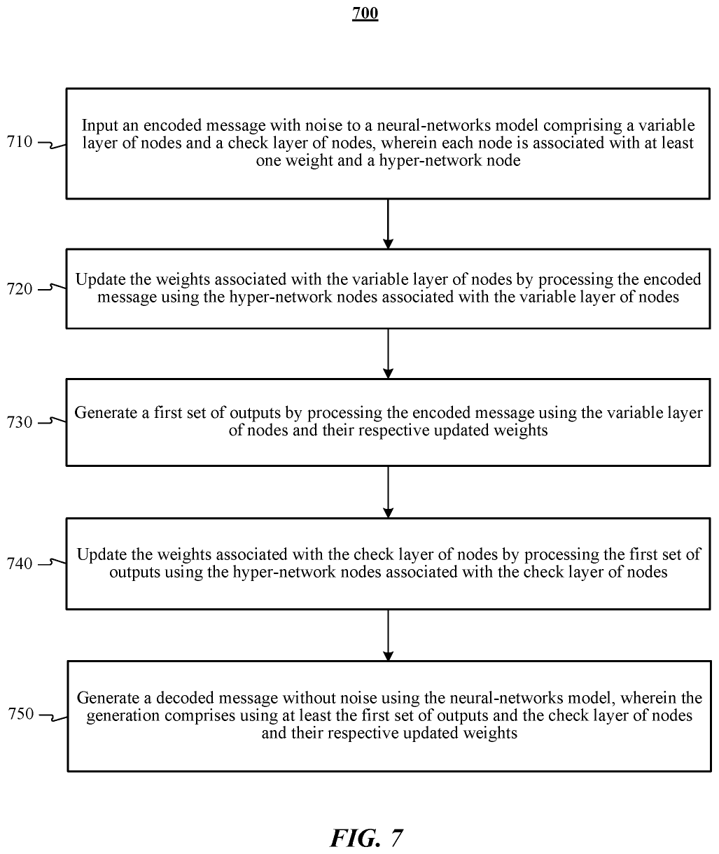

FIG. 7 illustrates an example method 700 for decoding messages using a hyper-graph network decoder. The method may begin at step 710, where the computing system 140 may input an encoded message with noise to a neural-networks model comprising a variable layer of nodes and a check layer of nodes, wherein each node is associated with at least one weight and a hyper-network node. At step 720, the computing system 140 may update the weights associated with the variable layer of nodes by processing the encoded message using the hyper-network nodes associated with the variable layer of nodes. At step 730, the computing system 140 may generate a first set of outputs by processing the encoded message using the variable layer of nodes and their respective updated weights. At step 740, the computing system 140 may update the weights associated with the check layer of nodes by processing the first set of outputs using the hyper-network nodes associated with the check layer of nodes. At step 750, the computing system 140 may generate a decoded message without noise using the neural-networks model, wherein the generation comprises using at least the first set of outputs and the check layer of nodes and their respective updated weights. Particular embodiments may repeat one or more steps of the method of FIG. 7, where appropriate. Although this disclosure describes and illustrates particular steps of the method of FIG. 7 as occurring in a particular order, this disclosure contemplates any suitable steps of the method of FIG. 7 occurring in any suitable order. Moreover, although this disclosure describes and illustrates an example method for decoding messages using a hyper-graph network decoder including the particular steps of the method of FIG. 7, this disclosure contemplates any suitable method for decoding messages using a hyper-graph network decoder including any suitable steps, which may include all, some, or none of the steps of the method of FIG. 7, where appropriate. Furthermore, although this disclosure describes and illustrates particular components, devices, or systems carrying out particular steps of the method of FIG. 7, this disclosure contemplates any suitable combination of any suitable components, devices, or systems carrying out any suitable steps of the method of FIG. 7.

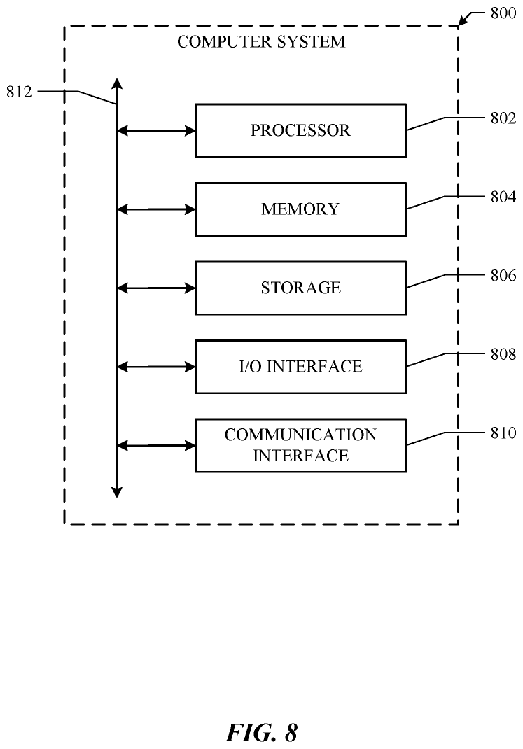

FIG. 8 illustrates an example computer system 800. In particular embodiments, one or more computer systems 800 perform one or more steps of one or more methods described or illustrated herein. In particular embodiments, one or more computer systems 800 provide functionality described or illustrated herein. In particular embodiments, software running on one or more computer systems 800 performs one or more steps of one or more methods described or illustrated herein or provides functionality described or illustrated herein. Particular embodiments include one or more portions of one or more computer systems 800. Herein, reference to a computer system may encompass a computing device, and vice versa, where appropriate. Moreover, reference to a computer system may encompass one or more computer systems, where appropriate.

This disclosure contemplates any suitable number of computer systems 800. This disclosure contemplates computer system 800 taking any suitable physical form. As example and not by way of limitation, computer system 800 may be an embedded computer system, a system-on-chip (SOC), a single-board computer system (SBC) (such as, for example, a computer-on-module (COM) or system-on-module (SOM)), a desktop computer system, a laptop or notebook computer system, an interactive kiosk, a mainframe, a mesh of computer systems, a mobile telephone, a personal digital assistant (PDA), a server, a tablet computer system, or a combination of two or more of these. Where appropriate, computer system 800 may include one or more computer systems 800; be unitary or distributed; span multiple locations; span multiple machines; span multiple data centers; or reside in a cloud, which may include one or more cloud components in one or more networks. Where appropriate, one or more computer systems 800 may perform without substantial spatial or temporal limitation one or more steps of one or more methods described or illustrated herein. As an example and not by way of limitation, one or more computer systems 800 may perform in real time or in batch mode one or more steps of one or more methods described or illustrated herein. One or more computer systems 800 may perform at different times or at different locations one or more steps of one or more methods described or illustrated herein, where appropriate.

In particular embodiments, computer system 800 includes a processor 802, memory 804, storage 806, an input/output (I/O) interface 808, a communication interface 810, and a bus 812. Although this disclosure describes and illustrates a particular computer system having a particular number of particular components in a particular arrangement, this disclosure contemplates any suitable computer system having any suitable number of any suitable components in any suitable arrangement.

In particular embodiments, processor 802 includes hardware for executing instructions, such as those making up a computer program. As an example and not by way of limitation, to execute instructions, processor 802 may retrieve (or fetch) the instructions from an internal register, an internal cache, memory 804, or storage 806; decode and execute them; and then write one or more results to an internal register, an internal cache, memory 804, or storage 806. In particular embodiments, processor 802 may include one or more internal caches for data, instructions, or addresses. This disclosure contemplates processor 802 including any suitable number of any suitable internal caches, where appropriate. As an example and not by way of limitation, processor 802 may include one or more instruction caches, one or more data caches, and one or more translation lookaside buffers (TLBs). Instructions in the instruction caches may be copies of instructions in memory 804 or storage 806, and the instruction caches may speed up retrieval of those instructions by processor 802. Data in the data caches may be copies of data in memory 804 or storage 806 for instructions executing at processor 802 to operate on; the results of previous instructions executed at processor 802 for access by subsequent instructions executing at processor 802 or for writing to memory 804 or storage 806; or other suitable data. The data caches may speed up read or write operations by processor 802. The TLBs may speed up virtual-address translation for processor 802. In particular embodiments, processor 802 may include one or more internal registers for data, instructions, or addresses. This disclosure contemplates processor 802 including any suitable number of any suitable internal registers, where appropriate. Where appropriate, processor 802 may include one or more arithmetic logic units (ALUs); be a multi-core processor; or include one or more processors 802. Although this disclosure describes and illustrates a particular processor, this disclosure contemplates any suitable processor.

In particular embodiments, memory 804 includes main memory for storing instructions for processor 802 to execute or data for processor 802 to operate on. As an example and not by way of limitation, computer system 800 may load instructions from storage 806 or another source (such as, for example, another computer system 800) to memory 804. Processor 802 may then load the instructions from memory 804 to an internal register or internal cache. To execute the instructions, processor 802 may retrieve the instructions from the internal register or internal cache and decode them. During or after execution of the instructions, processor 802 may write one or more results (which may be intermediate or final results) to the internal register or internal cache. Processor 802 may then write one or more of those results to memory 804. In particular embodiments, processor 802 executes only instructions in one or more internal registers or internal caches or in memory 804 (as opposed to storage 806 or elsewhere) and operates only on data in one or more internal registers or internal caches or in memory 804 (as opposed to storage 806 or elsewhere). One or more memory buses (which may each include an address bus and a data bus) may couple processor 802 to memory 804. Bus 812 may include one or more memory buses, as described below. In particular embodiments, one or more memory management units (MMUs) reside between processor 802 and memory 804 and facilitate accesses to memory 804 requested by processor 802. In particular embodiments, memory 804 includes random access memory (RAM). This RAM may be volatile memory, where appropriate. Where appropriate, this RAM may be dynamic RAM (DRAM) or static RAM (SRAM). Moreover, where appropriate, this RAM may be single-ported or multi-ported RAM. This disclosure contemplates any suitable RAM. Memory 804 may include one or more memories 804, where appropriate. Although this disclosure describes and illustrates particular memory, this disclosure contemplates any suitable memory.

In particular embodiments, storage 806 includes mass storage for data or instructions. As an example and not by way of limitation, storage 806 may include a hard disk drive (HDD), a floppy disk drive, flash memory, an optical disc, a magneto-optical disc, magnetic tape, or a Universal Serial Bus (USB) drive or a combination of two or more of these. Storage 806 may include removable or non-removable (or fixed) media, where appropriate. Storage 806 may be internal or external to computer system 800, where appropriate. In particular embodiments, storage 806 is non-volatile, solid-state memory. In particular embodiments, storage 806 includes read-only memory (ROM). Where appropriate, this ROM may be mask-programmed ROM, programmable ROM (PROM), erasable PROM (EPROM), electrically erasable PROM (EEPROM), electrically alterable ROM (EAROM), or flash memory or a combination of two or more of these. This disclosure contemplates mass storage 806 taking any suitable physical form. Storage 806 may include one or more storage control units facilitating communication between processor 802 and storage 806, where appropriate. Where appropriate, storage 806 may include one or more storages 806. Although this disclosure describes and illustrates particular storage, this disclosure contemplates any suitable storage.

In particular embodiments, I/O interface 808 includes hardware, software, or both, providing one or more interfaces for communication between computer system 800 and one or more I/O devices. Computer system 800 may include one or more of these I/O devices, where appropriate. One or more of these I/O devices may enable communication between a person and computer system 800. As an example and not by way of limitation, an I/O device may include a keyboard, keypad, microphone, monitor, mouse, printer, scanner, speaker, still camera, stylus, tablet, touch screen, trackball, video camera, another suitable I/O device or a combination of two or more of these. An I/O device may include one or more sensors. This disclosure contemplates any suitable I/O devices and any suitable I/O interfaces 808 for them. Where appropriate, I/O interface 808 may include one or more device or software drivers enabling processor 802 to drive one or more of these I/O devices. I/O interface 808 may include one or more I/O interfaces 808, where appropriate. Although this disclosure describes and illustrates a particular I/O interface, this disclosure contemplates any suitable I/O interface.

In particular embodiments, communication interface 810 includes hardware, software, or both providing one or more interfaces for communication (such as, for example, packet-based communication) between computer system 800 and one or more other computer systems 800 or one or more networks. As an example and not by way of limitation, communication interface 810 may include a network interface controller (NIC) or network adapter for communicating with an Ethernet or other wire-based network or a wireless NIC (WNIC) or wireless adapter for communicating with a wireless network, such as a WI-FI network. This disclosure contemplates any suitable network and any suitable communication interface 810 for it. As an example and not by way of limitation, computer system 800 may communicate with an ad hoc network, a personal area network (PAN), a local area network (LAN), a wide area network (WAN), a metropolitan area network (MAN), or one or more portions of the Internet or a combination of two or more of these. One or more portions of one or more of these networks may be wired or wireless. As an example, computer system 800 may communicate with a wireless PAN (WPAN) (such as, for example, a BLUETOOTH WPAN), a WI-FI network, a WI-MAX network, a cellular telephone network (such as, for example, a Global System for Mobile Communications (GSM) network), or other suitable wireless network or a combination of two or more of these. Computer system 800 may include any suitable communication interface 810 for any of these networks, where appropriate. Communication interface 810 may include one or more communication interfaces 810, where appropriate. Although this disclosure describes and illustrates a particular communication interface, this disclosure contemplates any suitable communication interface.

[87] In particular embodiments, bus 812 includes hardware, software, or both coupling components of computer system 800 to each other. As an example and not by way of limitation, bus 812 may include an Accelerated Graphics Port (AGP) or other graphics bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local (VLB) bus, or another suitable bus or a combination of two or more of these. Bus 812 may include one or more buses 812, where appropriate. Although this disclosure describes and illustrates a particular bus, this disclosure contemplates any suitable bus or interconnect.

Herein, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

What is claimed is:

1. A method comprising, by one or more computing systems:
inputting an encoded message with noise to a neural-networks model comprising a variable layer of nodes and a check layer of nodes, wherein each node is associated with at least one weight and a hyper-network node;
updating the weights associated with the variable layer of nodes by processing the encoded message using the hyper-network nodes associated with the variable layer of nodes;
generating a first set of outputs by processing the encoded message using the variable layer of nodes and their respective updated weights;
updating the weights associated with the check layer of nodes by processing the first set of outputs using the hyper-network nodes associated with the check layer of nodes; and
generating a decoded message without noise using the neural-networks model, wherein the generation comprises using at least the first set of outputs and the check layer of nodes and their respective updated weights.

2. The method of claim 1, further comprising:
applying an absolute value of the encoded message.

3. The method of claim 1, wherein the encoded message with noise is based on one or more of:
Bose-Chaudhuri-Hocquenghem (BCH) code;
low density parity check (LDPC) code; or
polar code.

4. The method of claim 1, wherein each hyper-network node is associated with an activation function.

5. The method of claim 4, wherein the activation function comprises one or more of:
a tanh activation function;
an arctanh activation function; or
a Taylor approximation of an arctanh activation function.

6. The method of claim 4, wherein updating the weights associated with the variable layer of nodes by processing the encoded message with noise using the hyper-network nodes associated with the variable layer of nodes is based on the activation functions.

7. The method of claim 4, wherein updating the weights associated with the check layer of nodes by processing the first set of outputs using the hyper-network nodes associated with the check layer of nodes is based on the activation functions.

8. The method of claim 4, wherein each activation function is associated with a damping factor.

9. The method of claim 8, wherein updating the weights associated with the variable layer of nodes by processing the encoded message with noise using the hyper-network nodes associated with the variable layer of nodes is based on the activation functions and their respective damping factors.

10. The method of claim 8, wherein updating the weights associated with the check layer of nodes by processing the first set of outputs using the hyper-network nodes associated with the check layer of nodes is based on the activation functions and their respective damping factors.

11. The method of claim 1, further comprising:
applying a binary generator matrix and a binary parity check matrix to the encoded message with noise.

12. The method of claim 1, wherein the neural-networks model is trained based on a plurality of training examples, wherein each training example is generated as a zero codeword transmitted over an additive white Gaussian noise, and wherein each training example is associated with a distinct signal-to-noise (SNR) value.

13. One or more computer-readable non-transitory storage media embodying software that is operable when executed to:
input an encoded message with noise to a neural-networks model comprising a variable layer of nodes and a check layer of nodes, wherein each node is associated with at least one weight and a hyper-network node;
update the weights associated with the variable layer of nodes by processing the encoded message using the hyper-network nodes associated with the variable layer of nodes;
generate a first set of outputs by processing the encoded message using the variable layer of nodes and their respective updated weights;
update the weights associated with the check layer of nodes by processing the first set of outputs using the hyper-network nodes associated with the check layer of nodes; and
generate a decoded message without noise using the neural-networks model, wherein the generation comprises using at least the first set of outputs and the check layer of nodes and their respective updated weights.

14. The media of claim 13, wherein the software is further operable when executed to:
apply an absolute value of the encoded message.

15. The media of claim 13, wherein the encoded message with noise is based on one or more of:
Bose-Chaudhuri-Hocquenghem (BCH) code;
low density parity check (LDPC) code; or
polar code.

16. The media of claim 13, wherein each hyper-network node is associated with an activation function.

17. The media of claim 16, wherein the activation function comprises one or more of:
a tanh activation function;
an arctanh activation function; or
a Taylor approximation of an arctanh activation function.

18. The media of claim 16, wherein updating the weights associated with the variable layer of nodes by processing the encoded message with noise using the hyper-network nodes associated with the variable layer of nodes is based on the activation functions.

19. The media of claim 16, wherein updating the weights associated with the check layer of nodes by processing the first set of outputs using the hyper-network nodes associated with the check layer of nodes is based on the activation functions.

20. A system comprising: one or more processors; and a non-transitory memory coupled to the processors comprising instructions executable by the processors, the processors operable when executing the instructions to:
input an encoded message with noise to a neural-networks model comprising a variable layer of nodes and a check layer of nodes, wherein each node is associated with at least one weight and a hyper-network node;
update the weights associated with the variable layer of nodes by processing the encoded message using the hyper-network nodes associated with the variable layer of nodes;
generate a first set of outputs by processing the encoded message using the variable layer of nodes and their respective updated weights;
update the weights associated with the check layer of nodes by processing the first set of outputs using the hyper-network nodes associated with the check layer of nodes; and
generate a decoded message without noise using the neural-networks model, wherein the generation comprises using at least the first set of outputs and the check layer of nodes and their respective updated weights.
